(19) United States
(12) Patent Application Publication
(10) Pub. No.: US 2025/0052842 A1
(43) Pub. Date: Feb. 13, 2025

(54) SYSTEM AND METHOD FOR SUPER-RESOLUTION OF MAGNETIC RESONANCE IMAGES USING SLICE-PROFILE-TRANSFORMATION AND NEURAL NETWORKS

(71) Applicant: The Regents of the University of California, Oakland, CA (US)

(72) Inventors: Kyung Hyun Sung, Los Angeles, CA (US); Jiahao Lin, Los Angeles, CA (US)

(21) Appl. No.: 18/712,624

(22) PCT Filed: Nov. 23, 2022
(86) PCT No.: PCT/US2022/050962

§ 371 Date: May 22, 2024

Related U.S. Application Data
(60) Provisional application No. 63/282,447, filed on Nov. 23, 2021.

(51) Int. Cl. G01R 33/56; G01R 33/483; G01R 33/561; G06T 3/4046; G06T 3/4053; G06T 11/00

(52) U.S. Cl. CPC G01R 33/5608; G01R 33/4835; G01R 33/5615; G06T 3/4046; G06T 3/4053; G06T 11/006; G06T 2211/441

(57) ABSTRACT

A system for super-resolution of magnetic resonance (MR) images includes an input for receiving a two-dimensional (2D) multi-slice MR dataset of a subject, a pre-processing module coupled to the input and configured to generate a convolved input from the received 2D multi-slice MR dataset by applying slice-profile convolution to the received 2D multi-slice MR dataset, a through plane super resolution neural network coupled to the pre-processing module and configured to generate a through-plane super-resolution imaging volume based on the convolved input, and a post-processing module coupled to the through plane super resolution neural network and configured to generate a three-dimensional (3D) isotropic super resolution imaging volume by applying slice-profile deconvolution. The through plane super resolution neural network can be trained using a training input dataset generated by applying slice-profile downsampling to a 2D multi-slice MR training dataset.

### CROSS-REFERENCE TO RELATED APPLICATIONS

This application is based on, claims priority to, and incorporates herein by reference in its entirety U.S. Ser. No. 63/282,447 filed Nov. 23, 2021 and entitled “Deep Learning Super-Resolution Magnetic Resonance Imaging Via Slice-Profile-Transformation.”

### BACKGROUND

Spin-echo based acquisitions, such as turbo spin-echo (TSE) or fast spin-echo (FSE) imaging, are preferred for clinical magnetic resonance imaging (MRI) image interpretation for high spatial and contrast resolution for detection of pathology because, for example, they can be reformatted into preferred orientations. Three-dimensional (3D) TSE imaging is limited by its long imaging time and related blur image artifact associated with patient motion. Instead, multi-slice two-dimensional (2D) TSE imaging is the standard for a range of clinical applications, due to its spin-echo-based acquisitions with high contrast and high in-plane resolution (e.g., 0.3-1 mm). However, a set of 2D slices in a multi-slice 2D acquisition typically has much thicker through-plane resolution (e.g., 3-6 mm), yielding low-resolution (LR) multi-planar reformation (MPR) with staircase artifact due to elongated voxels. As a result, multiple 2D TSE scans are often acquired in multiple orthogonal imaging planes (e.g., axial, coronal, and sagittal planes), and in some applications, up to five imaging planes (axial, coronal, sagittal and two oblique planes). These approaches increase the overall scan time, decrease patient comfort, and can also limit the streamlined interpretation of images (e.g., radiologists may need to draw a region of interest (ROI) separately on multiple 2D scans from different orientations). Accordingly, multi-slice two-dimensional (2D) TSE imaging is limited clinically by poor through-plane resolution due to elongated voxels and inability to generate multi-planar reformations (MPR) due to staircase artifact. Therefore, methods that achieve super-resolution (SR) transformation of a single TSE scan into a high-resolution (HR) isotropic 3D MRI dataset can be valuable to reduce overall imaging time and to improve the interpretation of TSE MRI.

Deep learning SR algorithms are the state-of-the-art for SR in natural images and have become increasingly popular for SR in MRI. Many studies have focused on SR of 3D MRI or in-plane SR for 2D MRI and have shown promise in achieving high in-plane resolution. However, applying them to achieve high through-plane resolution is challenging with multi-slice 2D TSE imaging dataset, because the super-resolution algorithms were trained and tested along the frequency and phase encoding directions. Frequency and phase encoding schemes divide the voxels evenly in the frequency domain, where they are continuous, uniform, and non-overlapping. In this case, training input for super-resolution can be easily synthesized by downsampling HR reference images. In contrast, multi-slice 2D TSE imaging is realized by applying a radiofrequency (RF)-excitation pulse with a slice-selection profile for each individual slice. Due to MR hardware limitations, the slice-selection profiles may not be sharp-edged and can overlap with adjacent slices. To compensate, slice spacing greater than the slice thickness is often used to avoid the slice overlapping, resulting in physical discrepancies between the evenly spaced super-resolution and through-plane resolution of multi-slice 2D TSE imaging. Training input for super-resolution cannot be easily synthesized by simple downsampling due to the fundamental difference between actual through-plane resolution and synthesized low-resolution images.

It would be desirable to provide systems and methods for super-resolution of MR images that address and/or overcome at least some of the deficiencies of prior approaches.

### SUMMARY

In accordance with an embodiment, a system for super-resolution of magnetic resonance (MR) images includes an input for receiving a two-dimensional (2D) multi-slice MR dataset of a subject, a pre-processing module coupled to the input and configured to generate a convolved input from the received 2D multi-slice MR dataset by applying slice-profile convolution to the received 2D multi-slice MR dataset, a through-plane super-resolution neural network coupled to the pre-processing module and configured to generate a through-plane super-resolution imaging volume based on the convolved input, and a post-processing module coupled to the through-plane super-resolution neural network and configured to generate a three-dimensional (3D) isotropic super-resolution imaging volume by applying slice-profile deconvolution to the through-plane super-resolution imaging volume. The through-plane super-resolution neural network can be trained using a training input dataset generated by applying slice-profile downsampling to a 2D multi-slice coronal MR training dataset.

In accordance with another embodiment, a method for super-resolution of magnetic resonance (MR) images includes receiving a two-dimensional (2D) multi-slice MR dataset of a subject, generating a convolved input from the received 2D multi-slice MR dataset by applying slice-profile convolution to the received 2D multi-slice MR dataset, generating a through-plane super-resolution imaging volume based on the convolved input using a through-plane super-resolution neural network, and generating a three-dimensional (3D) isotropic super-resolution imaging volume by applying slice-profile deconvolution to the through-plane super-resolution imaging volume.

### BRIEF DESCRIPTION OF THE DRAWINGS

The present disclosure will hereafter be described with reference to the accompanying drawings, wherein like reference numerals denote like elements.

FIG. 1 is a schematic diagram of an example magnetic resonance imaging (MRI) system in accordance with an embodiment;

FIG. 2 is a block diagram of a system for super-resolution of magnetic resonance (MR) images in accordance with an embodiment;

FIG. 3 illustrates a method for super-resolution of magnetic resonance (MR) images in accordance with an embodiment;

FIG. 4 illustrates a method for training a deep generative network for generating a through-plane SR volume in accordance with an embodiment;

FIG. 5 illustrates an example network architecture that may be used to implement the through-plane super-resolution neural network in accordance with an embodiment; and

FIG. 6 is a block diagram of an example computer system in accordance with an embodiment.

### DETAILED DESCRIPTION

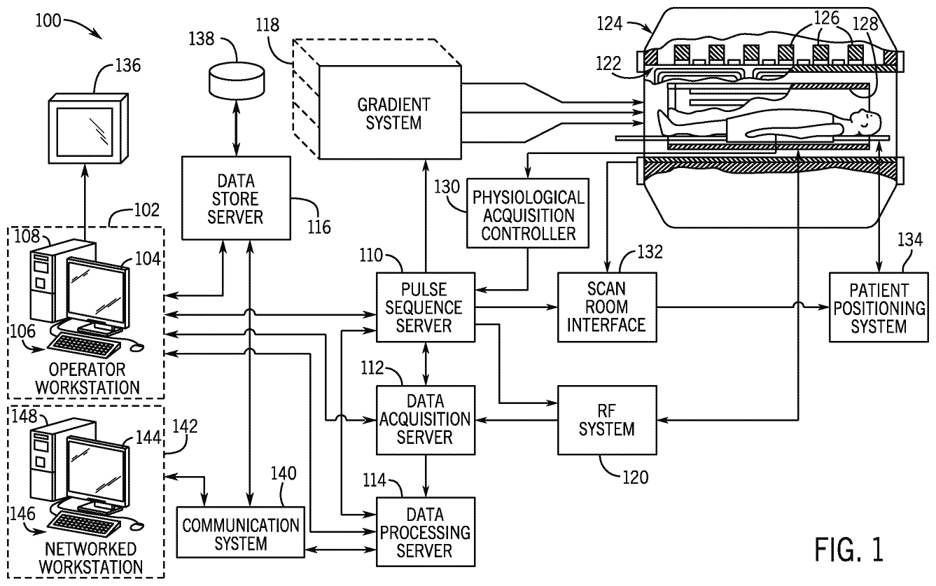

FIG. 1 shows an example of an MRI system 100 that may be used to perform the methods described herein. MRI system 100 includes an operator workstation 102, which may include a display 104, one or more input devices 106 (e.g., a keyboard, a mouse), and a processor 108. The processor 108 may include a commercially available programmable machine running a commercially available operating system. The operator workstation 102 provides an operator interface that facilitates entering scan parameters into the MRI system 100. The operator workstation 102 may be coupled to different servers, including, for example, a pulse sequence server 110, a data acquisition server 112, a data processing server 114, and a data store server 116. The operator workstation 102 and the servers 110, 112, 114, and 116 may be connected via a communication system 140, which may include wired or wireless network connections.

The pulse sequence server 110 functions in response to instructions provided by the operator workstation 102 to operate a gradient system 118 and a radiofrequency (“RF”) system 120. Gradient waveforms for performing a prescribed scan are produced and applied to the gradient system 118, which then excites gradient coils in an assembly 122 to produce the magnetic field gradients Gₓ, G_{y}, and Gₓ that are used for spatially encoding magnetic resonance signals. The gradient coil assembly 122 forms part of a magnet assembly 124 that includes a polarizing magnet 126 and a whole-body RF coil 128.

RF waveforms are applied by the RF system 120 to the RF coil 128, or a separate local coil to perform the prescribed magnetic resonance pulse sequence. Responsive magnetic resonance signals detected by the RF coil 128, or a separate local coil, are received by the RF system 120. The responsive magnetic resonance signals may be amplified, demodulated, filtered, and digitized under direction of commands produced by the pulse sequence server 110. The RF system 120 includes an RF transmitter for producing a wide variety of RF pulses used in MRI pulse sequences. The RF transmitter is responsive to the prescribed scan and direction from the pulse sequence server 110 to produce RF pulses of the desired frequency, phase, and pulse amplitude waveform. The generated RF pulses may be applied to the whole-body RF coil 128 or to one or more local coils or coil arrays.

The RF system 120 also includes one or more RF receiver channels. An RF receiver channel includes an RF preamplifier that amplifies the magnetic resonance signal received by the coil 128 to which it is connected, and a detector that detects and digitizes the I and Q quadrature components of the received magnetic resonance signal. The magnitude of the received magnetic resonance signal may, therefore, be determined at a sampled point by the square root of the sum of the squares of the I and Q components:

$$M = \sqrt{{I}^{2} + {Q}^{2}} \qquad ( 1 )$$

and the phase of the received magnetic resonance signal may also be determined according to the following relationship:

$$φ = {tan}^{- 1} ( \frac{Q}{I} ) \qquad ( 2 )$$

The pulse sequence server 110 may receive patient data from a physiological acquisition controller 130. By way of example, the physiological acquisition controller 130 may receive signals from a number of different sensors connected to the patient, including electrocardiograph (“ECG”) signals from electrodes, or respiratory signals from a respiratory bellows or other respiratory monitoring devices. These signals may be used by the pulse sequence server 110 to synchronize, or “gate,” the performance of the scan with the subject's heartbeat or respiration.

The pulse sequence server 110 may also connect to a scan room interface circuit 132 that receives signals from various sensors associated with the condition of the patient and the magnet system. Through the scan room interface circuit 132, a patient positioning system 134 can receive commands to move the patient to desired positions during the scan.

The digitized magnetic resonance signal samples produced by the RF system 120 are received by the data acquisition server 112. The data acquisition server 112 operates in response to instructions downloaded from the operator workstation 102 to receive the real-time magnetic resonance data and provide buffer storage, so that data is not lost by data overrun. In some scans, the data acquisition server 112 passes the acquired magnetic resonance data to the data processor server 114. In scans that require information derived from acquired magnetic resonance data to control the further performance of the scan, the data acquisition server 112 may be programmed to produce such information and convey it to the pulse sequence server 110. For example, during pre-scans, magnetic resonance data may be acquired and used to calibrate the pulse sequence performed by the pulse sequence server 110. As another example, navigator signals may be acquired and used to adjust the operating parameters of the RF system 120 or the gradient system 118, or to control the view order in which k-space is sampled. In still another example, the data acquisition server 112 may also process magnetic resonance signals used to detect the arrival of a contrast agent in a magnetic resonance angiography (“MRA”) scan. For example, the data acquisition server 112 may acquire magnetic resonance data and processes it in real-time to produce information that is used to control the scan.

The data processing server 114 receives magnetic resonance data from the data acquisition server 112 and processes the magnetic resonance data in accordance with instructions provided by the operator workstation 102. Such processing may include, for example, reconstructing two-dimensional or three-dimensional images by performing a Fourier transformation of raw k-space data, performing other image reconstruction algorithms (e.g., iterative or back-projection reconstruction algorithms), applying filters to raw k-space data or to reconstructed images, generating functional magnetic resonance images, or calculating motion or flow images.

Images reconstructed by the data processing server 114 are conveyed back to the operator workstation 102 for storage. Real-time images may be stored in a data base memory cache, from which they may be output to operator display 104 or a display 136. Batch mode images or selected real time images may be stored in a host database on disc storage 138. When such images have been reconstructed and transferred to storage, the data processing server 114 may notify the data store server 116 on the operator workstation 102. The operator workstation 102 may be used by an operator to archive the images, produce films, or send the images via a network to other facilities.

The MRI system 100 may also include one or more networked workstations 142. For example, a networked workstation 142 may include a display 144, one or more input devices 146 (e.g., a keyboard, a mouse), and a processor 148. The networked workstation 142 may be located within the same facility as the operator workstation 102, or in a different facility, such as a different healthcare institution or clinic.

The networked workstation 142 may gain remote access to the data processing server 114 or data store server 116 via the communication system 140. Accordingly, multiple networked workstations 142 may have access to the data processing server 114 and the data store server 116. In this manner, magnetic resonance data, reconstructed images, or other data may be exchanged between the data processing server 114 or the data store server 116 and the networked workstations 142, such that the data or images may be remotely processed by a networked workstation 142.

The present disclosure describes a slice-profile transformation super-resolution (SPTSR) framework with deep learning for through-plane super-resolution (SR) of a two-dimensional (2D) multi-slice MR dataset (or scan) of a subject. In some embodiments, the 2D multi slice MR dataset (or scan) of the subject can be acquired using known 2D multi-slice MRI acquisition techniques including, for example, turbo spin-echo (TSE) imaging, fast spin-echo (FSE) imaging, etc. The 2D multi-slice MR dataset of the subject may be, for example, a T₁-weighted scan, a T₂-weighted scan, a proton density weighted scan, etc. The disclosed SPTSR framework can be configured to generate a three dimensional (3D) isotropic super-resolution imaging volume based on the 2D multi-slice MR dataset of the subject. The disclosed SPTSR systems and methods may be used for MRI applications that utilize 2D multi-slice sequences including, but not limited to, knee, prostate, brain, placenta, and fetal brain. In some embodiments, the 2D multi-slice MR dataset of the subject may be pre-processed by applying a slice profile convolution to generate a convolved input which may be provided to a through-plane super-resolution neural network. In some embodiments, the application of the slice profile convolution may include reformatting the 2D multi-slice MR dataset of the subject to an orthogonal plane. The through-plane super-resolution neural network may be configured to generate a through-plane super-resolution imaging volume. The through-plane super-resolution neural network may be implemented using known deep leaning models or architectures such as, for example, a deep generative network.

In some embodiments, the through-plane super-resolution neural network can be trained using training data that includes a synthesized low-resolution (LR) training input dataset that can be synthesized by applying slice-profile downsampling (SP-downsampling) to 2D multi-slice MR training datasets (or scans). In some embodiments, the low-resolution training input dataset synthesized by the SP-downsampling method can provide a realistic representation of low-resolution through-plane images. In some embodiments, the through-plane super-resolution neural network may be trained using a 2D multi-slice MR training dataset in a first orientation (or imaging plane) and the trained through-plane super-resolution neural network may be used in an inference process using a 2D multi-slice MR dataset of the subject in an orthogonal orientation (or imaging plane) of the first orientation. For example, in some embodiments, the 2D multi-slice MR training dataset may be a coronal dataset or scan and the 2D multi-slice MR dataset of the subject may be an axial dataset or scan.

In some embodiments, the through-plane super-resolution imaging volume generated by the through-plane super-resolution neural network may be slice-profile deconvolved to generate a 3D isotropic super-resolution imaging volume that has an isotropic resolution (e.g., 0.625 mm)³). The disclosed systems and methods for super-resolution of MR images that utilize the SPTSR framework can provide excellent overall image quality with excellent sharpness, minimal artifacts, and low noise level. The disclosed systems and method for super-resolution of MR images can advantageously transform the 2D multi-slice MR training dataset used for training of the through-plane super-resolution neural network and the input 2D multi-slice MR dataset of the subject used for inference by the through-plane super-resolution neural network to a common low-resolution image domain. The disclosed SPTSR framework advantageously takes slice profiles into consideration which jointly bridges the physical differences between the training data used to train the through-plane super-resolution neural network and the multi-slice MR dataset of the subject which is used for the inference process using the trained through-plane super-resolution neural network.

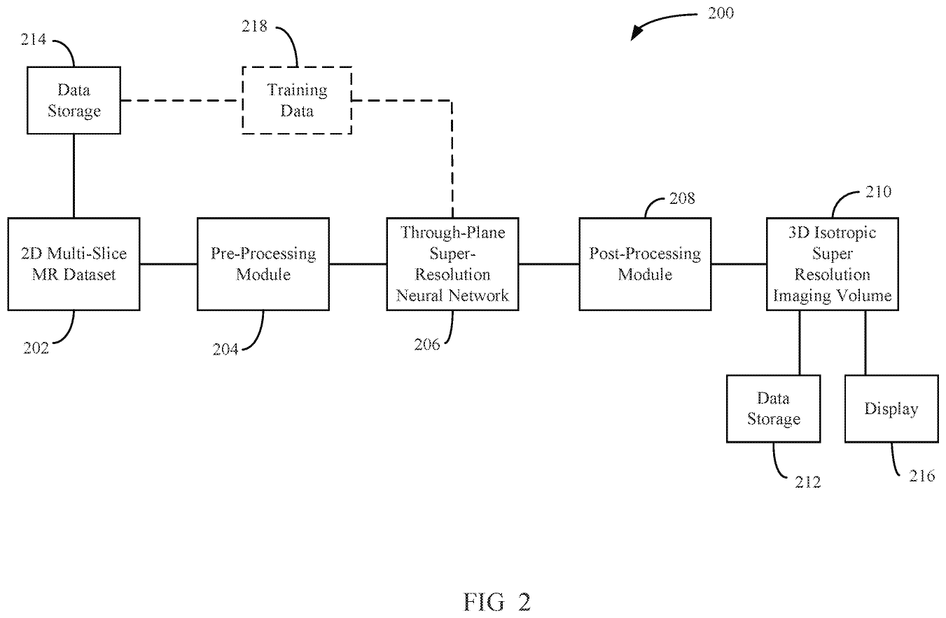

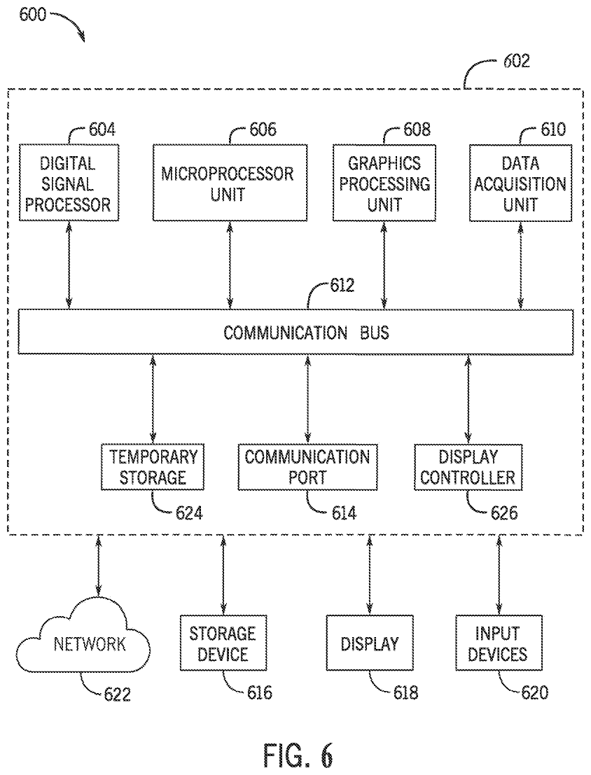

FIG. 2 is a block diagram of a system for super-resolution of magnetic resonance (MR) images in accordance with an embodiment. System 200 can include an input of a two-dimensional (2D) multi-slice MR dataset (or scan) 202 of a subject, a pre-processing module 204, a trained through-plane super-resolution neural network 206, a post-processing module 208, an output of an isotropic super-resolution 3D MR volume 210, data storage, 212, 214, and a display 216. The 2D multi-slice MR dataset 202 of a subject may include a plurality of slices having a slice spacing and may be acquired in an orientation or imaging plane (e.g., axial, coronal, sagittal). In some embodiments, the 2D multi slice MR dataset (or scan) 202 of the subject can be acquired using known 2D multi-slice MRI acquisition techniques including, for example, turbo spin-echo (TSE) imaging, fast spin-echo (FSE) imaging, etc. The 2D multi-slice MR dataset of the subject may be, for example, a T₁-weighted scan, a T₂-weighted scan, a proton density weighted scan, etc. In some embodiments, the input 2D multi-slice MR dataset 202 of the subject may be retrieved from data storage (or memory) 214 of system 200, data storage of an imaging system (e.g., disc storage 138 of MRI system 100 shown in FIG. 1), or data storage of other computer systems (e.g., storage device 616 of computer system 600 shown in FIG. 6). In some embodiments, the input 2D multi-slice MR dataset 202 of the subject may be acquired in real time from the subject using an MRI system (e.g., MRI system 100 shown in FIG. 1). For example, MR data can be acquired from a subject using a pulse sequence performed on the MRI system and configured to acquire 2D multi-slice MR data from the subject. For example, in some embodiments, a turbo spin-echo (TSE) imaging technique or a fast spin-echo (FSE) imaging technique may be used to acquire 2D multi-slice MR data.

The 2D multi-slice MR dataset 202 of the subject may be provided as input to the pre-processing module 204. The pre-processing module 202 may be configured to generate a convolved input based on the received 2D multi-slice MR dataset 202. For example, the pre-processing module may be configured to apply a slice profile convolution to the 2D multi-slice MR dataset 202 to generate the convolved input. In some embodiments, the application of the slice profile convolution may include reformatting the 2D multi-slice MR dataset 202 of the subject to an orthogonal plane. For example, if the 2D multi-slice MR dataset 202 is an axial MR scan, the pre-processing module 204 may be configured to reformat the axial scan to an orthogonal plane such as, for example, a coronal view. While the following description of FIGS. 2-4 may refer to an example where the 2D multi-slice MR dataset 202 of the subject is an axial scan and the convolved input is in an orthogonal plane such as the coronal plane, it should be understood that in some embodiments, other combinations of an orientation for the 2D multi-slice MR dataset 202 and orthogonal plane (to the orientation of dataset 202) may be used. In some embodiments, the 2D multi-slice MR dataset 202 of the subject may also be cropped before application of the slice profile convolution. Advantageously, the slice-profile convolved input can result in the overlap of image voxels in the slice direction. The convolved input generated by the pre-processing module 204 may be provided to the through-plane super-resolution neural network 206. In some embodiments, three consecutive slices of the convolved input may be provided to the through-plane super-resolution neural network 206, for example, the input may include a convolved center slice and two adjacent slices. A three-slice input may advantageously borrow image information from the adjacent slice which can help the through-plane super-resolution results of the neural network 206 and system 200 and may also preserve the inter-slice consistency across the image volume and benefit the isotropic super-resolution results of system 200.

In some embodiments, the through-plane super-resolution neural network 206 may be configured to generate a through-plane super-resolution imaging volume based on the convolved input generated from the 2D multi-slice MR dataset 202 of the subject. In some embodiments, the inference output (i.e., the generated through-plane super-resolution imaging volume) of the through-plane super-resolution neural network 206 advantageously has isotropic voxel spacing. In some embodiments, the through-plane super-resolution neural network may be implemented using known deep learning network models or network architectures. In some embodiments, the through-plane super-resolution neural network 206 may be implemented as a deep generative network such as, for example, an adversarial generative network. An example network architecture that may be used to implement the through-plane super-resolution neural network 206 is discussed further below with respect to FIG. 6.

In some embodiments, the through-plane super-resolution neural network 206 can be trained using training data 218. In some embodiments, the training data 218 can include a plurality of 2D multi-slice MR training datasets (or scans) and a synthesized low-resolution (LR) training input dataset corresponding to one or more of the 2D multi-slice MR training datasets. In some embodiments, the 2D multi-slice MR training datasets may be existing datasets (or scans) that were acquired using known 2D multi-slice MRI acquisition techniques including, for example, turbo spin-echo (TSE) imaging, fast spin-echo (FSE) imaging, etc. The 2D multi-slice MR training datasets may be, for example, a T₁-weighted scan, a T₂-weighted scan, a proton density weighted scan, etc. Each 2D multi-slice MR training dataset may include a plurality of slices having a slice spacing and may be acquired in an orientation or imaging plane (e.g., axial, coronal, sagittal). While the following description of FIGS. 2-4 may refer to an example where a 2D multi-slice MR training dataset 202 of the training data 218 is a coronal scan, it should be understood that in some embodiments, the 2D multi-slice MR training dataset may have other orientations. In some embodiments, the 2D multi-sluice MR training dataset used for training of neural network 206 may have an orthogonal orientation (or imaging plane) to the 2D multi-slice MR dataset 202 of the subject used as input during the inference process. In some embodiments, the 2D multi-slice MR training dataset may be cropped before generating a low-resolution training input dataset.

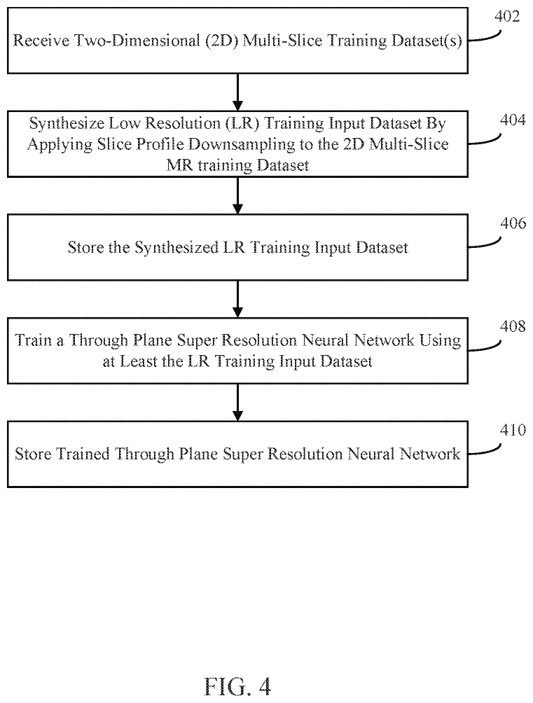

A low-resolution training input dataset may be generated by applying slice profile downsampling to a 2D multi-slice MR training dataset. For example, as discussed further below, each line of pixels of the low-resolution training input dataset may be generated by multiplying a slice profile (PSF) of length L to the same physical location in the 2D multi-slice MR training dataset. In some embodiments, a low-resolution training input dataset synthesized by the SP-downsampling method can provide a realistic representation of low-resolution through-plane images. In some embodiments, the low-resolution training input dataset and the 2D multi-slice MR training dataset (or scan) may be used as a low-resolution and high-resolution, respectively, training pair for the through-plane super-resolution neural network 206 during a training process. In some embodiments, the training data 218 may be retrieved from data storage (or memory) 214 of system 200, data storage of an imaging system (e.g., MRI system 100 shown I FIG. 1), or data storage of other computer systems (e.g., storage device 616 of computer system 600 shown in FIG. 6). Known training methods may be used to train the through-plane super-resolution neural network 206 to analyze the input 2D multi-slice MR dataset 202 and generate a through-plane super-resolution imaging volume. For example, in embodiments where the through-plane super-resolution neural network is a deep generative network, a Wasserstein generative adversarial network with gradient penalty (WGAN-GP) training scheme may be used to train the through pane super-resolution neural network 206. An example method for training the through-plane super-resolution neural network 206 is described further below with respect to FIG. 4.

In some embodiments, three consecutive slices of the low-resolution training input dataset may be provided as input to the through-plane super-resolution neural network 206 during training, for example, the input may include a target center slice and two adjacent slices. By using a three-slice low-resolution input with adjacent slices, the through-plane super-resolution neural network 206 can learn the spatial relationship between image slices. Because of imperfect slice excitation, the voxel information can be intertwined between adjacent slices, further helping the through-plane super-resolution neural network 206 to generate though plane super-resolution imaging volumes. In some embodiments, the output of the through-plane super-resolution neural network 206 during training can be the same resolution, matrix size and contrast compared to the 2D multi-slice MR training dataset.

As mentioned, the through-plane super-resolution neural network 206 may be configured to generate an output, for example a through-plane super-resolution volume, that may then be provided to a post-processing module 208. The post-processing module 208 may be configured to generate a three-dimensional (3D) isotropic super-resolution imaging volume 210 based on the through-plane super-resolution volume. The output through-plane super-resolution imaging volume from the trained through-plane super-resolution neural network 206 will still be convolved. In some embodiments, the post processing module 208 may be configured to apply slice-profile deconvolution to the through-plane super-resolution imaging volume generated by the through-plane super-resolution neural network 206. For example, in some embodiments, the slice profile deconvolution may be an iterative Richardson-Lucy deconvolution. The slice profile deconvolution may be used to advantageously resolve artifacts (e.g., smearing artifacts) in the imaging plane of the convolved input which can result in a 3D isotropic super-resolution imaging volume with non-overlapping cubic voxels. In some embodiments, the 3D isotropic super-resolution imaging volume may have an isotropic resolution (e.g., 0.625 mm)³). The 3D isotropic super-resolution imaging volume 210 may be displayed on a display 216 (e.g., displays 104, 136, 144 of the MRI system 100 shown in FIG. 1 or display 618 of the computer system 600 shown in FIG. 6). The 3D isotropic super-resolution imaging volume 210 may also be stored in data storage, for example, data storage 214 (e.g., device storage 616 of computer system 600 shown in FIG. 6).

In some embodiments, the pre-processing module 204, the through-plane super-resolution neural network 206, and the post-processing module 208 may be implemented on one or more processors (or processor devices) of computer system such as, for example, any general purpose computing system or device such as a personal computer, workstation, cellular phone, smartphone, laptop, tablet, or the like. As such, the computer system may include any suitable hardware and component designed or capable of carrying out a variety of processing and control tasks, including, but not limited to, steps for receiving a 2D multi-slice MR dataset (or scan) of the subject, implementing the pre-processing module 204, implementing the through-plane super-resolution neural network 206, implementing the post-processing module 208, providing the 3D isotropic super-resolution imaging volume 210 to a display 216 or storing the 3D isotropic super-resolution imaging volume 210 in data storage 212. For example, the computer system may include a programmable processor or combination of programmable processors, such as central processing units (CPUs), graphics processing units (GPUs), and the like. In some implementations, the one or more processors of the computer system may be configured to execute instructions stored in a non-transitory computer readable-media. In this regard, the computer system may be any device or system designed to integrate a variety of software, hardware, capabilities, and functionalities. Alternatively, and by way of particular configurations and programming, the computer system may be a special-purpose system or device. For instance, such special purpose system or device may include one or more dedicated processing units or modules that may be configured (e.g., hardwired, or pre-programmed) to carry out steps, in accordance with aspects of the present disclosure.

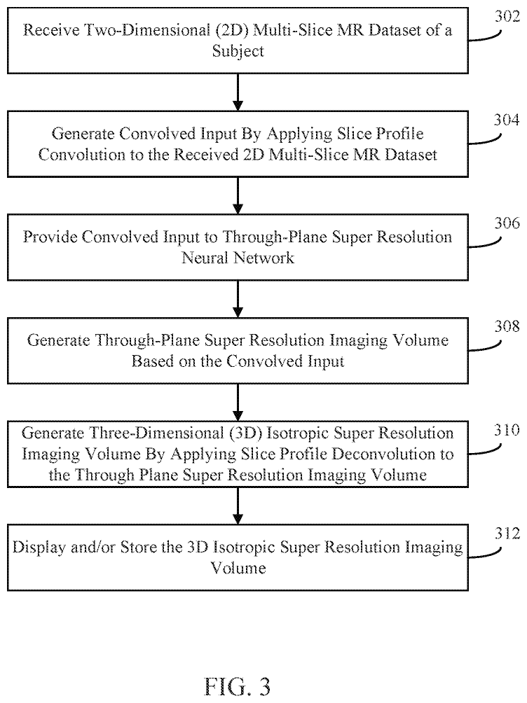

FIG. 3 illustrates a method for super-resolution of MR images in accordance with an embodiment. The process illustrated in FIG. 3 is described below as being carried out by the system 200 for super-resolution of MR images as illustrated in FIG. 2. Although the blocks of the process are illustrated in a particular order, in some embodiments, one or more blocks may be executed in a different order than illustrated in FIG. 3, or may be bypassed.

At block 302, a 2D multi-slice MR dataset (or scan) 202 of a subject is received by the system 200. The 2D multi-slice MR dataset 202 of a subject may include a plurality of slices having a slice spacing and may be acquired in an orientation or imaging plane (e.g., axial, coronal, sagittal). In some embodiments, the 2D multi slice MR dataset (or scan) 202 of the subject can be acquired using known 2D multi-slice MRI acquisition techniques including, for example, turbo spin-echo (TSE) imaging, fast spin-echo (FSE) imaging, etc. The 2D multi-slice MR dataset of the subject may be, for example, a T₁-weighted scan, a T₂-weighted scan, a proton density weighted scan, etc. In some embodiments, the input 2D multi-slice MR dataset may retrieved from data storage 214 of system 200, data storage of an imaging system (e.g., disc storage 138 of MRI system 100 shown in FIG. 1) or data storage of other computer systems (e.g., storage device 616 of computer system 600 shown in FIG. 6). As discussed above, in some embodiments, the 2D multi-slice MR dataset 202 may be acquired in real time from a subject using an MRI system (e.g., MRI system 100 shown in FIG. 1).

At block 304, a convolved input may be generated by applying a slice profile convolution to the received 2D multi-slice MR dataset, for example, using pre-processing module 202. While the following description refers to an example where the 2D multi-slice MR dataset 202 of the subject is an axial scan and the convolved input is in an orthogonal plane such as the coronal plane, it should be understood that in some embodiments, other combinations of an orientation for the 2D multi-slice MR dataset 202 and orthogonal plane (to the orientation of dataset 202) may be used. In an example, the variable V can be defined as an underlying isotropic high-resolution 3D imaging volume with a matrix size of NX×NY×NZ and field-of-view (FOV) of FX×FY×FZ. Then, a multi-slice 2D coronal scan I_{xz} and a multi-slice 2D axial scan I_{xy} at the same FOV may be expressed as:

$${I}_{xz} ( x , s , z ) {\vert}_{x ∈ [ 1 , NX ] , s ∈ [ 1 , {NSL}_{xz} ] , z ∈ [ 1 , NZ ]} = {\sum }_{j = s \times \frac{FY}{{NSL}_{xz}} - ⌊ \frac{L}{2} - 1 ⌋}^{j = s \times \frac{FY}{{NSL}_{xz}} + ⌊ \frac{L}{2} ⌋} {PSF}_{y} ( j ) V ( x , j , z ) , \qquad ( 3 )$$

$${I}_{xy} ( x , y , s ) {\vert}_{x ∈ [ 1 , NX ] , y ∈ [ 1 , NY ] , s ∈ [ 1 , {NSL}_{xy} ]} = {\sum }_{k = s \times \frac{FZ}{{NSL}_{xy}} - ⌊ \frac{L}{2} - 1 ⌋}^{k = s \times \frac{FZ}{{NSL}_{xy}} + ⌊ \frac{L}{2} ⌋} {PSF}_{z} ( k ) V ( x , y , k ) , \qquad ( 4 )$$

where PSF_{y} and PSF_{z} are the normalized one-dimensional (1D) slice profile for a given RF-excitation pulse in coronal and axial scans, NSL_{xz} and NSL_{xy} are the number of slices of the coronal and axial scans, x, y, z, s are the pixel and slice indices. L is the slice thickness, which is full-width-half-max (FWHM) of PSF, and the PSF is approximated as truncated sinc function. In some embodiments, it may be possible to compute the true slice profile by the combination of slice profiles of RF excitation and refocusing pulses, however, the difference between exact and approximated ones would be subtle. In some embodiments, the disclosed method can apply projection to all signals.

As mentioned, in some embodiments, an axial scan (I_{xy}) may be used for the 2D multi-slice MR dataset 202. For inference in the disclosed SPTSR framework, in some embodiments, the 2D multi-slice MR dataset 202 (e.g., I_{xy}) can be convolved with slice profile PSF_{y} to form the convolved input I_{xy,conv}, which, in this example, may be defined as:

$${I}_{xy , conv} ( x , y , z ) {\vert}_{x ∈ [ 1 , NX ] , y ∈ [ 1 , NY ] , z ∈ [ 1 , {NSL}_{xy} ]} = {\sum }_{j = s \times \frac{FY}{{NSL}_{xz}} - ⌊ \frac{L}{2} - 1 ⌋}^{j = s \times \frac{FY}{{NSL}_{xz}} + ⌊ \frac{L}{2} ⌋} {PSF}_{y} ( j ) {I}_{xy} ( x , j , z ) . \qquad ( 5 )$$

Note that, in some embodiments, the dimension is NY in the y-direction, and the matrix size of I_{xy} can be kept by applying a sliding window for the convolved input I_{xy,conv}.

In some embodiments, the application of the slice profile convolution may include reformatting the 2D multi-slice MR dataset 202 of the subject to an orthogonal plane. For example, if the 2D multi-slice MR dataset 202 is an axial MR scan, the pre-processing module 204 may be configured to reformat the axial scan to an orthogonal plane such as, for example, a coronal view. In some embodiments, the 2D multi-slice MR dataset 202 of the subject may also be cropped before application of the slice profile convolution. Advantageously, the slice-profile convolved input can result in the overlap of image voxels in the slice direction.

At block 306, the convolved input may be provided to a through-plane super-resolution neural network 206. In some embodiments, three consecutive slices of the convolved input may be provided to the through-plane super-resolution neural network 206, for example, the input may include a convolved center slice and two adjacent slices. A three-slice input may advantageously borrow image information from the adjacent slice which can help the through-plane super-resolution results of the neural network 206 and system 200 and may also preserve the inter-slice consistency across the image volume and benefit the isotropic super-resolution results of system 200. At block 308, a through-plane super-resolution imaging volume may be generated based on the convolved input using the through-plane super-resolution neural network 206. In some embodiments, the inference output (i.e., the generated through-plane super-resolution imaging volume) of the through-plane super-resolution neural network 206 advantageously has isotropic voxel spacing. In some embodiments, the through-plane super-resolution neural network may be implemented using known deep learning network models or network architectures. In some embodiments, the through-plane super-resolution neural network 206 may be implemented as a deep generative network such as, for example, am adversarial generative network. As discussed above with respect to FIG. 2, the through-plane super-resolution neural network 206 may advantageously be trained using a low-resolution training input dataset synthesized using slice profile downsampling on a 2D multi-slice MR training dataset. An example method for training the through-plane super-resolution neural network 206 is described further below with respect to FIG. 4.

At block 310, a 3D isotropic super-resolution imaging volume may be generated by applying slice profile deconvolution to the through-plane super-resolution imaging volume, for example, using post-processing module 208. As mentioned above, the through-plane super-resolution imaging volume generated by the through-plane super-resolution neural network 206 may have isotropic voxel spacing. In some embodiments, to fully utilize this isotropic voxel spacing characteristic, the through-plane super-resolution imaging volume may be deconvolved with a 1D slice profile. For example, in the example above where the 2D multi-slice MR dataset 202 is an axial scan (I_{xy}), the through-plane super-resolution imaging volume (SR_{xy}) may be deconvolved with the 1D slice profile PDF_{y}. The result is the isotropic super-resolution imaging volume SR_{xy,deconv}. In some embodiments, by using an iterative noise-robust deconvolution method, the through-plane super-resolution imaging volume (SR_{xy}) can be transformed with an elongated voxel size of (FX/NX,FY/NSLₐₓ,FZ/NZ), to an isotropic high-resolution image volume SR_{xy,deconv}, with isotropic voxel size (FX/NX,FY/NY,FZ/NZ). The slice profile deconvolution may be used to advantageously resolve artifacts (e.g., smearing artifacts) in the imaging plane of the convolved input which can result in a 3D isotropic super-resolution imaging volume with non-overlapping cubic voxels. At block 312, the generated 3D isotropic super-resolution imaging volume may be displayed on a display 216 (e.g., displays 104, 136, 144 of the MRI system 100 shown in FIG. 1 or display 618 of the computer system 600 shown in FIG. 6). The generated 3D isotropic super-resolution imaging volume may also be stored in data storage, for example, data storage 212 (e.g., disc storage 138 of the MRI system 100 shown in FIG. 1 or device storage 616 of computer system 600 shown in FIG. 6).

FIG. 4 illustrates a method for training a deep generative network for generating a through-plane SR volume in accordance with an embodiment. Although the blocks of the process in FIG. 4 are illustrated in a particular order, in some embodiments, one or more blocks may be executed in a different order than illustrated in FIG. 4, or may be bypassed.

At block 402, in some embodiments training data (e.g., training data 218 shown in FIG. 2) may be retrieved from data storage (e.g., data storage 214 of system 200 shown in FIG. 2). In some embodiments, the training data can include a plurality of 2D multi-slice MR training datasets (or scans). In some embodiments, the 2D multi-slice MR training datasets may be existing datasets (or scans) that were acquired using known 2D multi-slice MRI acquisition techniques including, for example, turbo spin-echo (TSE) imaging, fast spin-echo (FSE) imaging, etc. The 2D multi-slice MR training datasets may be, for example, a T₁-weighted scan, a T₂-weighted scan, a proton density weighted scan, etc. Each 2D multi-slice MR training dataset may include a plurality of slices having a slice spacing and may be acquired in an orientation or imaging plane (e.g., axial, coronal, sagittal). In some embodiments, the 2D multi-slice MR training dataset used for training of neural network 206 may have an orthogonal orientation (or imaging plane) to the 2D multi-slice MR dataset 202 of the subject used as input during the inference process. In some embodiments, the 2D multi-slice MR training dataset may be cropped before generating a low-resolution training input dataset.

At block 404, a low-resolution (LR) training input dataset may be synthesized by applying slice profile downsampling to the 2D multi-slice MR training dataset. For example, as discussed further below, each line of pixels of the low-resolution training input dataset may be generated by multiplying a slice profile (PSF) of length L to the same physical location in the 2D multi-slice MR training dataset. In an example, in some embodiments for the SPTSR framework, the 2D multi-slice MR training dataset used for training may be a 2D coronal scan, I_{xz}, (with high-resolution in the z-direction). While the following description refers to an example where the 2D multi-slice MR training dataset is a coronal scan, it should be understood that in some embodiments, datasets with other orientations (or imaging planes) may be used. In some embodiments, the 2D multi-slice MR training dataset can have an orientation (or imaging plane) orthogonal to the orientation of 2D multi-slice MR dataset 202 used for inference with the trained through-plane super-resolution neural network 206. As mentioned above, the disclosed SPTSR framework can advantageously transforms both I_{xz} and I_{xy} to the common low-resolution image domain by considering both slice profiles PSF_{y} and PSF_{z}. To synthesize a low-resolution training input dataset with the example training coronal scan I_{xz}, the training coronal scan I_{xz} can be convolved with slice profile PSF_{z}. Accordingly, in this example, the low-resolution training input dataset may be given by:

$${LR}_{xz} ( x , y , z ) {\vert}_{x ∈ [ 1 , NX ] , y ∈ [ 1 , {NSL}_{xz} ] , z ∈ [ 1 , {NSL}_{xy} ]} = {\sum }_{k = s \times \frac{FZ}{{NSL}_{xy}} - ⌊ \frac{L}{2} - 1 ⌋}^{k = s \times \frac{FZ}{{NSL}_{xy}} + ⌊ \frac{L}{2} ⌋} {PSF}_{z} ( k ) {I}_{xz} ( x , y , k ) \qquad ( 6 )$$

In some embodiments, a low-resolution training input dataset synthesized by the SP-downsampling method can provide a realistic representation of low-resolution through-plane images. At block 406, the synthesized low-resolution training input dataset may be stored in data storage, for example, data storage 214 shown in FIG. 2.

At block 408, the through-plane super-resolution neural network 206 may be trained using at least the synthesized low-resolution training input dataset. In some embodiments, the through-plane super-resolution neural network may be implemented using known deep learning network models or network architectures. In some embodiments, the through-plane super-resolution neural network 206 may be implemented as a deep generative network such as, for example, am adversarial generative network. Known training methods may be used to train the through-plane super-resolution neural network 206 to analyze the input 2D multi-slice MR dataset 202 and generate a through-plane super-resolution imaging volume. For example, in embodiments where the through-plane super-resolution neural network is a deep generative network, a Wasserstein generative adversarial network with gradient penalty (WGAN-GP) training scheme may be used to train the through pane super-resolution neural network 206. In some embodiments, three consecutive slices of the low-resolution training input dataset may be provided as input to the through-plane super-resolution neural network 206 during training, for example, the input may include a target center slice and two adjacent slices. By using a three-slice low-resolution input with adjacent slices, the through-plane super-resolution neural network 206 can learn the spatial relationship between image slices. Because of imperfect slice excitation, the voxel information can be intertwined between adjacent slices, further helping the through-plane super-resolution neural network 206 to generate though plane super-resolution imaging volumes. In some embodiments, the output of the through-plane super-resolution neural network during training can be the same resolution, matrix size and contrast compared to the 2D multi-slice MR training dataset.

As mentioned above, in some embodiments, the low-resolution training input dataset and the 2D multi-slice MR training dataset (or scan) may be used as a low-resolution and high-resolution, respectively, training pair for the through-plane super-resolution neural network 206 during a training process. For the example discussed above at block 404 where the 2D multi-slice MR training dataset is a coronal scan I_{xz}, the low-resolution training input dataset, LR_{xz}, and the training coronal scan, I_{xz}, can form a low-resolution (LR)-high-resolution (HR) training pair for the through-plane super-resolution networks. The output of the though plane super-resolution neural network during training may have same dimension and voxel size as the HR reference (I_{xz}). At block 410, the trained through-plane super-resolution neural network 206 may be stored in data storage, for example, data storage 214 shown in FIG. 2.

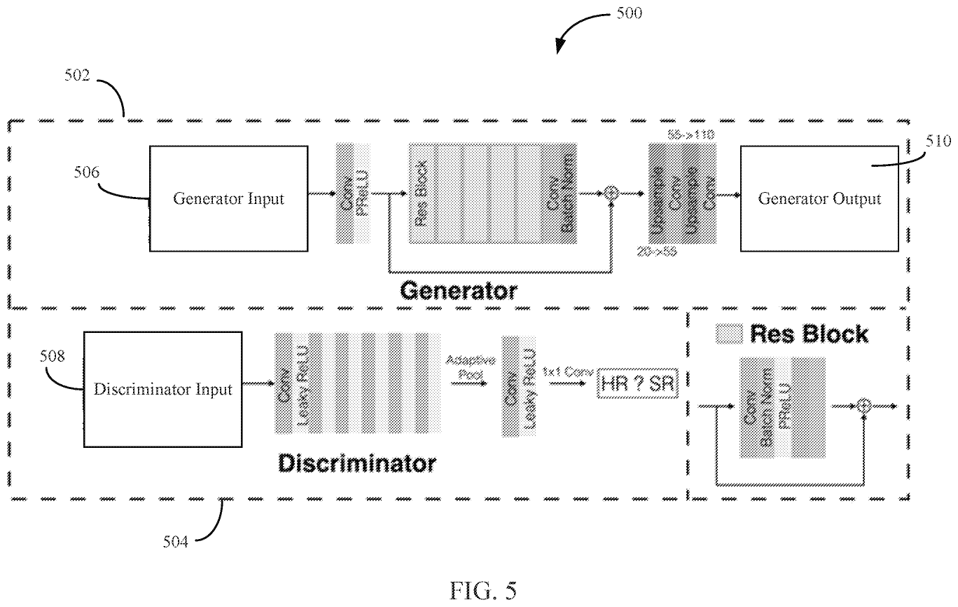

FIG. 5 illustrates an example network architecture that may be used to implement the through-plane super-resolution neural network in accordance with an embodiment. The illustrated network 500 is an example deep generative network that may be used to implement the through-plane super-resolution neural network 206 (shown in FIG. 2). The network 500 includes a generator 502 and a discriminator 504. The discriminator 504 may be used in a training process for the generator 502. During training of the network 500, a training input formed by slice profile downsampling a 2D multi-slice MR training dataset (as described above with respect to FIGS. 2-4) may be provided as an input 506 to the generator 502 and a 2D multi-slice MR training dataset (or scan) may be provided as an input 508 to the discriminator. The 2D multi-slice MR training dataset input to the discriminator can be used as a reference image for training. During inference using the trained generator 502, a convolved input (as described above with respect to FIGS. 2 and 3) may be provided as an input 506 to the generator 502. The trained generator 502 may generate a through-plane super-resolution imaging volume as an output 510. In some embodiments, the upsampling blocks in the generator 502 may be implemented as 1D isotropic upsampling.

As discussed above, in some embodiments, the generator input 506 for both training and inference may be three consecutive slices with the middle slice being a target input with the two adjacent slices. By adding the adjacent slices, the deep generative network 500 may learn the spatial relationship between the image slices. Because of imperfect slice excitation, the voxel information can be intertwined between adjacent slices, further helping the deep generative network 500 to generate though plane super-resolution imaging volumes.

FIG. 6 is a block diagram of an example computer system in accordance with an embodiment. Computer system 600 may be used to implement the systems and methods described herein. In some embodiments, the computer system 600 may be a workstation, a notebook computer, a tablet device, a mobile device, a multimedia device, a network server, a mainframe, one or more controllers, one or more microcontrollers, or any other general-purpose or application-specific computing device. The computer system 600 may operate autonomously or semi-autonomously, or may read executable software instructions from the memory or storage device 616 or a computer-readable medium (e.g., a hard drive, a CD-ROM, flash memory), or may receive instructions via the input device 620 from a user, or any other source logically connected to a computer or device, such as another networked computer or server. Thus, in some embodiments, the computer system 600 can also include any suitable device for reading computer-readable storage media.

Data, such as data acquired with, for example, an imaging system (e.g., a magnetic resonance imaging (MRI) system, etc.), may be provided to the computer system 600 from a data storage device 616, and these data are received in a processing unit 602. In some embodiments, the processing unit 602 included one or more processors. For example, the processing unit 602 may include one or more of a digital signal processor (DSP) 604, a microprocessor unit (MPU) 606, and a graphic processing unit (GPU) 608. The processing unit 602 also includes a data acquisition unit 610 that is configured to electronically receive data to be processed. The DSP 604, MPU 606, GPU 608, and data acquisition unit 610 are all coupled to a communication bus 612. The communication bus 612 may be, for example, a group of wires, or a hardware used for switching data between the peripherals or between any component in the processing unit 602.

The processing unit 602 may also include a communication port 614 in electronic communication with other devices, which may include a storage device 616, a display 618, and one or more input devices 620. Examples of an input device 620 include, but are not limited to, a keyboard, a mouse, and a touch screen through which a user can provide an input. The storage device 616 may be configured to store data, which may include data such as, for example, training data, multi-slice 2D MR images, through-plane super-resolution imaging volumes, and isotropic super-resolution 3D imaging volumes, etc., whether these data are provided to, or processed by, the processing unit 602. The display 618 may be used to display images and other information, such as patient health data, and so on.

The processing unit 602 can also be in electronic communication with a network 622 to transmit and receive data and other information. The communication port 614 can also be coupled to the processing unit 602 through a switched central resource, for example the communication bus 612. The processing unit 602 can also include temporary storage 624 and a display controller 626. The temporary storage 624 is configured to store temporary information. For example, the temporary storage can be a random-access memory.

Computer-executable instructions for super-resolution of magnetic resonance (MR) images according to the above-described methods may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital volatile disks (DVD) or other optical storage, magnetic cassettes, magnetic tape, magnetic disk storage or other magnetic storage devices, or any other medium which can be used to store the desired instructions and which may be accessed by a system (e.g., a computer), including by internet or other computer network form of access.

The present invention has been described in terms of one or more preferred embodiments, and it should be appreciated that many equivalents, alternatives, variations, and modifications, aside from those expressly stated, are possible and within the scope of the invention.

1. A system for super-resolution of magnetic resonance (MR) images, the system comprising:
an input for receiving a two-dimensional (2D) multi-slice MR dataset of a subject;
a pre-processing module coupled to the input and configured to generate a convolved input from the received 2D multi-slice MR dataset by applying slice-profile convolution to the received 2D multi-slice MR dataset;
a through-plane super-resolution neural network coupled to the pre-processing module and configured to generate a through-plane super-resolution imaging volume based on the convolved input; and
a post-processing module coupled to the through-plane super-resolution neural network and configured to generate a three-dimensional (3D) isotropic super-resolution imaging volume by applying slice-profile deconvolution to the through-plane super-resolution imaging volume.

2. The system according to claim 1, wherein the 2D multi-slice MR dataset is one of a turbo spin-echo (TSE) dataset or a fast spin-echo (FSE) dataset.

3. The system according to claim 2, wherein the 2D multi-slice MR dataset is one of a T₁-, T₂-, or proton density weighted dataset.

4. The system according to claim 1, wherein applying slice-profile convolution to the received 2D multi-slice MR dataset reformats the 2D multi-slice MR dataset to an orthogonal plane.

5. The system according to claim 1, wherein the convolved input comprises a convolved center slice and two adjacent slices.

6. The system according to claim 1, wherein the through-plane super-resolution neural network is a generative adversarial network.

7. The system according to claim 1, wherein the through-plane super-resolution neural network is trained using a training input dataset generated by applying slice-profile downsampling to a 2D multi-slice MR training dataset.

8. The system according to claim 7, wherein the training input dataset is a low-resolution training input dataset.

9. The system according to claim 7, wherein the training input dataset comprises three consecutive low-resolution images.

10. A method for super-resolution of magnetic resonance (MR) images, the method comprising:
receiving a two-dimensional (2D) multi-slice MR dataset of a subject;
generating, using a pre-processing module, a convolved input from the received 2D multi-slice MR dataset by applying slice-profile convolution to the received 2D multi-slice MR dataset;
generating, using a through-plane super-resolution neural network, a through-plane super-resolution imaging volume based on the convolved input; and
generating, using a post-processing module, a three-dimensional (3D) isotropic super-resolution imaging volume from the through-plane super-resolution imaging volume by applying slice-profile deconvolution to the through-plane super-resolution imaging volume.

11. The method according to claim 10, wherein the 2D multi-slice MR dataset is one of a turbo spin-echo (TSE) or fast spin-echo (FSE) dataset.

12. The method according to claim 11, wherein the 2D multi-slice MR dataset is one of a T1-, T2-, or proton density weighted dataset.

13. The method according to claim 10, wherein applying slice-profile convolution to the received 2D multi-slice MR dataset reformats the 2D multi-slice MR dataset to an orthogonal plane.

14. The method according to claim 10, wherein the convolved input comprises a convolved center slice and two adjacent slices.

15. The method according to claim 10, wherein the through-plane super-resolution neural network is a generative adversarial network.

16. The method according to claim 10, wherein the through-plane super-resolution neural network is trained using a training input dataset generated by applying slice-profile downsampling to a 2D multi-slice MR training dataset.

17. The method according to claim 16, wherein the training input dataset is a low-resolution training input dataset.

18. The method according to claim 16, wherein the training input dataset comprises three consecutive low-resolution images.

19. The method according to claim 16, wherein the 2D multi-slice MR training dataset is one of a turbo spin-echo (TSE) or fast spin-echo (FSE) dataset.
